(19) United States
(12) Patent Application Publication
(10) Pub. No.: US 2003/0122224 A1
(43) Pub. Date: Jul. 3, 2003

(54) Lead frame with dual thin film coated on inner lead terminal

(76) Inventors: Jung-Chun Shih, Jubei City (TW); Chin-Kuo Yu, Taichung (TW); Hung-Yi Wu, Jungli City (TW)

Correspondence Address: PERKINS COIE LLP, PATENT-SEA, P.O. BOX 1247, SEATTLE, WA, 98111-1247, US

(21) Appl. No.: 10/114,607

(22) Filed: Apr. 1, 2002

(30) Foreign Application Priority Data
Dec. 28, 2001 (TW) 90223582

(51) Int. Cl. H01L 23/495

(52) U.S. Cl. 257/676

(57) ABSTRACT

The present invention provides a lead frame structure for semiconductor package comprising a main frame, a die paddle located the central portion of the lead frame structure for locating a die thereon. A die pad supporting bar is connected to the main frame to support the die paddle, a plurality of outer leads is connected to the main frame and a plurality of inner leads surrounds the die paddle and connected to the outer lead. Wherein the terminal portion of the inner leads with dual thin layer structure includes a first conductive layer and a second conductive layer including gold to improve the bonding wire reliability.

### FIELD OF THE INVENTION

The present invention relates to a semiconductor package lead frame, and more specifically, to IC lead frame with dual layer coated on the inner lead to improve the bonding reliability.

### BACKGROUND OF THE INVENTION

With the rapid advances in the semiconductor package for semiconductor technology, designers are always tempted to scale the size of the package. The industry of the package is striving to reduce the size while simultaneously increasing their speed. The renewed interest in high density hybrid is driven by the requirement to handle large numbers of IC interconnections, the increasing clock rate of digital systems and the desire to pack greater functionality into smaller spaces. Therefore, the number of a package's leads becomes more and more. An important consideration in making small, high speed and high-density devices is providing packages capable of the spreading heat generated by the devices. A further problem confronting the technology is the relentless need for more I/O per die. The pitch between the lead of the lead frame is also reduced to meet the requirement.

The semiconductor die is located and mounted on the lead frame followed by coating an insulating layer thereon for isolation. Each inner lead aligns to corresponding bonding pad and connected to the bonding pad by using bonding wires. Typically, the die and the lead frame are encapsulated by molding compound.

U.S. Pat. No. 6,118,173 to Emoto, entitled “Lead frame and a semiconductor device”. The package includes a chip, inner leads reaches the periphery of the semiconductor chip, and bonding wires for electrically connecting the semiconductor chip and the inner leads. The semiconductor chip is fixed on a die pad portion, and a chip fixing inner lead is integrated with the die pad portion. To simplify the bonding wire connection process and improve the reliability, the chip fixing inner lead has a step portion so that the die pad portion is formed at a lower position than the inner leads. Further, U.S. Pat. No. 6,107,675 disclosed a lead frame structure.

There is a need to improve the adhesion reliability of the bonding wires while the bonding wires bonds on the bonding pads, and more specifically, the bonding area is reduced along with the device pitch is scaled down. How to improve the adhesion reliability becomes an important task for the lead frame technology. FIFURE 1 shows the prior art crossectional view of the inner lead of the lead frame, a silver thin film 300 coated on the substrate 100 to have a thickness of about 150 micron meter to 350 micron meter. The adhesive between the silver film 300 and the bonding wire is poor, therefore, the art cannot provide better bonding reliability.

What is need is a new structure for the inner lead structure to improve the bonding wire reliability.

### SUMMARY OF THE INVENTION

The object of the present invention is to provide a lead frame package with excellent bonding reliability.

A lead frame structure for semiconductor package comprising a main frame, a die paddle located the central portion of the lead frame structure for locating a die thereon. A die pad supporting bar is connected to the main frame to support the die paddle, a plurality of outer leads is connected to the main frame and a plurality of inner leads surrounds the die paddle and connected to the outer lead. Wherein the terminal portion of the inner leads with dual thin layer structure includes a first conductive layer and a second conductive layer including gold to improve the bonding wire reliability.

A lead frame semiconductor package comprising a semiconductor die having bonding pads formed thereon. A die paddle is located in the lead frame semiconductor package for locating the semiconductor die thereon. A plurality of inner leads surrounds the die paddle and wherein the terminal portion of the inner leads with dual thin layer structure including a first conductive layer and a second conductive layer including gold to improved the bonding wire reliability. Bonding wires is connected between the terminal of the inner leads and the bonding pads. A molding compound encapsulates the semiconductor die, the bonding wires, the die paddle for protection.

### BRIEF DESCRIPTION OF THE DRAWINGS

FIG. 1 is a cross section view of an inner lead structure according to the prior art.

FIG. 2 is a top view of a lead frame structure.

FIG. 2A is a cross section view of an inner lead structure according to the present invention.

FIG. 3 is a cross section view of a package with dual layer inner lead structure according to the present invention.

FIG. 4 is a top view of a package with dual layer inner lead structure according to the present invention.

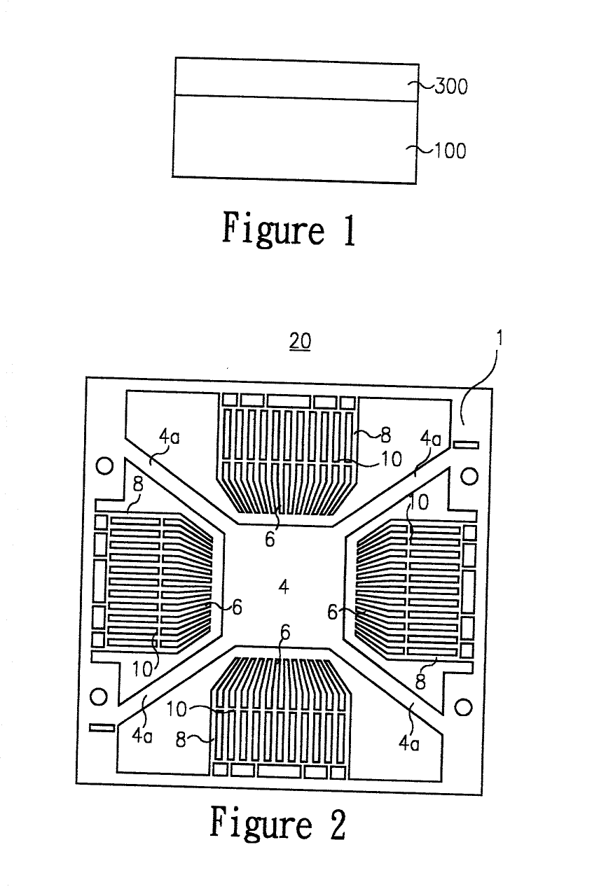

### DETAILED DESCRIPTION OF THE PREFERRED EMBODIMENT

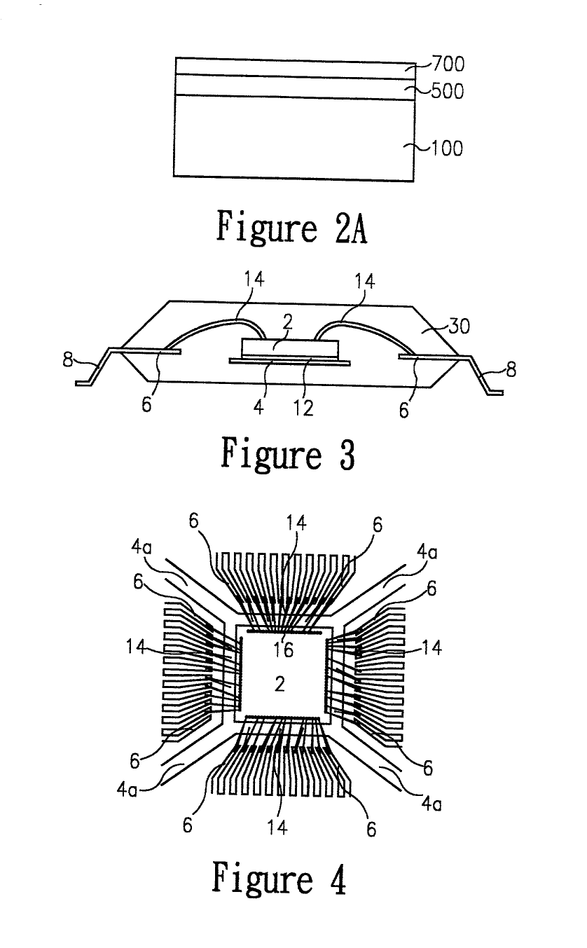

The present invention discloses a novel structure of lead frame structure for semiconductor package to improve the bonding reliability between the bonding wires and the bonding pad. Referring to FIG. 2 and 2A in conjunction with FIG. 3, the structure includes a main frame 1 to support each member of the lead frame 20. The central portion of the lead frame 20 is die paddle or die pad which is used for locating a die thereon. A die pad supporting bar 4a is connected to the main frame 1 to support the die pad 4. The function of the die pad 4 is to carry the die and may be formed by the material with excellent thermal conductivity. A plurality of inner leads 6 surrounds the die pad 4 as shown in the FIGUREs. The amount of the inner lead in the drawing is used for an example rather than limiting the scope of the present invention.

A plurality of outer leads 8 is connected to the main frame 1 and the inner lead 6 is connected to the outer lead 8. Dam bar 10 locates at the conjunction of the outer leads 8 and the inner leads 6 and lateral connected to each outer leads 8. The dam bar 10 prevents the molding compound from leaking while molding. The dam bar 10 will be separated after molding to avoid short circuit between leads 6.

The terminal portion of the inner leads 6 is used for bonding wire and the bonding area structure of the present invention is improved to increase the bonding wire reliability. Turning to FIG. 2A, a first conductive thin film 500 and a second conductive thin film 700 are respectively formed on the lead frame substrate 100. The lead frame substrate 100 can be selected from Copper or Copper alloy or Fe/Ni alloy. Preferably, the first conductive thin film 500 is formed by electroplate technology and formed of Silver or Nicole with a thickness at least about 50 micron meter. The second conductive thin film 700 is formed by gold using electroplate technology and it is almost the identical material with the bonding wires, therefore, the adhesion between the bonding wire and inner lead will be improved and the stress is reduced. The thickness of the layer 700 is about 15-50 micron meter. Further, the gold thin film 700 provides better conductivity than prior art and it can suffer higher external force. Thus, the novel structure can suffer higher stress and external force, thereby preventing the bonding wire from being damage by external force. Apparently, the bonding wire reliability will be improved.

Turning to FIG. 3, it illustrates the crossectional view of the package according to the present invention. A die 2 having bonding pad 16 formed thereon is formed on a die paddle or die pad 16 by using adhesive material 12. The material for forming the bonding pad 16 includes Aluminum. Adhesive material 12 is selected from conductive material or non-conductive material and the die 2 is carried by the die pad 16. Molding compound 30 seals all the members including die 2, bonding wire 14 and major part lead frame for protection. The character of the structure is that a gold thin film is coated on the surface of the inner lead 6, thereby forming a dual layer structure including silver/gold or silver/nickel. FIG. 4 illustrates the top view of the present invention. In an embodiment, a thickness of the first conductive layer of the dual thin film is about 40-60 micron meter and a thickness of the second conductive layer is about 2-5 micron meter. The second conductive layer 700 is formed on the first conductive layer 500.

The inner lead structure according to the present invention from bottom to top includes Copper layer/Silver layer/Gold layer, the silver layer is at least 50 micron meter and the thickness of the gold layer is 15 to 50 micron meter. The other structure can be Copper layer/Nicole layer/Gold layer, the Nicole layer is at least 50 micron meter. Alternative embodiment includes Fe/Ni alloy layer/Gold layer.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure. Thus, while the preferred embodiment of the invention has been illustrated and described, it will be appreciated that various changes can be made therein without departing from the spirit and scope of the invention.

The embodiments of the invention in which an exclusive property or privilege is claimed are defined as follows:

1. A lead frame structure for semiconductor package comprising:
a main frame;
a die paddle located the central portion of said lead frame structure for locating a die thereon;
a die pad supporting bar connected to said main frame to support said die paddle;
a plurality of outer leads connected to said main frame;
a plurality of inner leads surrounds said die paddle and connected to said outer lead; and
wherein the terminal portion of said inner leads with dual thin layer structure including a first conductive layer and a second conductive layer including gold to improve the bonding wire reliability.

2. The lead frame structure of claim 1, wherein said main frame is formed of Copper or Fe/Ni alloy.

3. The lead frame structure of claim 1, wherein said first conductive layer is formed of silver.

4. The lead frame structure of claim 3, wherein a thickness of said first conductive layer is at least 50 micron meter.

5. The lead frame structure of claim 3, wherein a thickness of said second conductive layer is about 15-50 micron meter.

6. The lead frame structure of claim 1, wherein said first conductive layer is formed of nickel.

7. The lead frame structure of claim 6, wherein a thickness of said first conductive layer is at least 50 micron meter.

8. The lead frame structure of claim 6, wherein a thickness of said second conductive layer is about 15-50 micron meter.

9. A lead frame semiconductor package comprising:
a semiconductor die having bonding pads formed thereon;
a die paddle located in said lead frame semiconductor package for locating said semiconductor die thereon;
a plurality of inner leads surrounds said die paddle and wherein the terminal portion of said inner leads with dual thin layer structure including a first conductive layer and a second conductive layer including gold to improved the bonding wire reliability;
bonding wires connected between said terminal of said inner leads and said bonding pads;
molding compound encapsulated said semiconductor die, said bonding wires, said die paddle for protection.

10. The lead frame semiconductor package of claim 9, wherein a lead frame of said lead frame semiconductor package is formed of Copper or Fe/Ni alloy.

11. The lead frame semiconductor package of claim 9, wherein said first conductive layer is formed of silver.

12. The lead frame semiconductor package of claim 11, wherein a thickness of said first conductive layer is at least 50 micron meter.

13. The lead frame semiconductor package of claim 11, wherein a thickness of said second conductive layer is about 15-50 micron meter.

14. The lead frame semiconductor package of claim 9, wherein said first conductive layer is formed of nickel.

15. The lead frame semiconductor package of claim 14, wherein a thickness of said first conductive layer is at least 50 micron meter.

16. The lead frame semiconductor package of claim 14, wherein a thickness of said second conductive layer is about 15-50 micron meter.
